(19) United States
(12) Patent Application Publication
(10) Pub. No.: US 2021/0005435 A1
(43) Pub. Date: Jan. 7, 2021

(54) METHODS, APPARATUS, AND SYSTEMS FOR PROCESSING A SUBSTRATE

(71) Applicant: APPLIED MATERIALS, INC., Santa Clara, CA (US)

(72) Inventors: Soonwook Jung, Campbell, CA (US); Laksheswar Kalita, SAN JOSE, CA (US); Tae S Cho, San Jose, CA (US); Kenneth D Schatz, SANTA CLARA, CA (US)

(21) Appl. No.: 16/460,277

(22) Filed: Jul. 2, 2019

(51) Int. Cl. H01J 37/32; G01N 21/3504

(52) U.S. Cl. CPC H01J 37/32972; G01N 21/3504; H01J 37/32834; H01J 37/32477

(57) ABSTRACT

Methods, apparatus, and systems for substrate processing are provided. Apparatus can include a controller; a processing chamber; a substrate supporting a substrate; and an infrared sensor assembly disposed adjacent the substrate support and comprising: a sample chamber one of made from or coated with nickel or nickel alloy and configured to collect chemicals which are present while the substrate is being processed in the processing chamber; an IR light source disposed at one end of the sample chamber and an IR detector disposed at an opposite end of the sample chamber; and a pair of windows positioned in an optical path between the IR light source and the IR detector, wherein the IR light source transmits IR light along the optical path and the IR detector detects the transmitted IR light and transmits a signal to the controller for determining a concentration of the chemicals present in the processing chamber.

### FIELD

Embodiments of the present disclosure generally relate to methods, apparatus, and systems for substrate processing, and more particularly, to methods, apparatus, and systems that use non-dispersive infrared (NDIR) sensors for processing a substrate.

### BACKGROUND

Processing chambers used for processing substrates can sometimes have highly caustic environments (e.g., use caustic chemicals, such as hydrofluoric (HF) acid or other caustic chemicals) that can limit the types of devices that can be used for monitoring one or more parameters associated with processing the substrate. For example, the inventors have found that when processing substrates in such environments (e.g., when using etch chambers), utilization of conventional chamber diagnostic systems, such as optical emission spectroscopy devices, residual gas analyzers (RGAs), self-plasma optical emission spectroscopy (OES) devices, can be challenging and/or impractical.

For example, some of the conventional chamber diagnostic systems have limited gas/chemical detection capabilities and may require additional gases be introduced into the chamber (or additional chemical reactions to occur within the chamber) to obtain accurate measurements while the substrate is being processed. Additionally, high energy electrons that are sometimes present in the highly caustic environments can react with other chemicals present within the chamber and can make decoupling radicals (e.g., fragmentation issue) difficult, which, in turn, can make it difficult to obtain accurate measurements while the substrate is being processed, etc.

Therefore, there exists a need for methods and apparatus that use an NDIR sensor suitable for use in caustic processing environments for processing a substrate.

### SUMMARY

Methods, apparatus, and systems for processing a substrate are provided herein. In some embodiments, for example, a system for processing a substrate can include a controller; a processing chamber defining an inner volume; a substrate support disposed in the processing chamber to support a substrate; and an infrared (IR) sensor assembly disposed in the inner volume of the processing chamber adjacent the substrate support and comprising: a sample chamber one of made from or coated with nickel or nickel alloy and configured to collect chemicals which are present while the substrate is being processed in the processing chamber; an IR light source disposed at one end of the sample chamber and an IR detector disposed at an opposite end of the sample chamber; and a pair of windows positioned in an optical path between the IR light source and the IR detector, wherein the IR light source transmits IR light along the optical path and the IR detector detects the transmitted IR light and transmits a signal to the controller for determining a concentration of the chemicals present in the processing chamber.

In accordance with some embodiments, there is provided a method for processing a substrate that can include loading a substrate onto a substrate support disposed in an inner volume defined in a processing chamber; while the substrate is being processed in the processing chamber, collecting chemicals, which are present in the processing chamber, using a sample chamber, which is one of made from or coated with nickel or nickel alloy, of an IR sensor assembly; transmitting, using an IR light source disposed at one end of the sample chamber, IR light through a pair of windows positioned along an optical path; detecting, using an IR detector disposed at an opposite end of the sample chamber, the transmitted IR light; and transmitting a signal from the IR detector to a controller in communication with the processing chamber for determining a concentration of the chemicals present in the processing chamber.

In accordance with some embodiments, there is provided a non-transitory computer readable storage medium having stored thereon a plurality of instructions that when executed cause a controller in communication with a processing chamber to perform a method for processing a substrate that can include loading a substrate onto a substrate support disposed in an inner volume defined in the processing chamber; while the substrate is being processed in the processing chamber, collecting chemicals, which are present in the processing chamber, using a sample chamber, which is one of made from or coated with nickel or nickel alloy, of an IR sensor assembly; transmitting, using an IR light source disposed at one end of the sample chamber, IR light through a pair of windows positioned along an optical path; detecting, using an IR detector disposed at an opposite end of the sample chamber, the transmitted IR light; and transmitting a signal from the IR detector to the controller in communication with the processing chamber for determining a concentration of the chemicals present in the processing chamber.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a cross sectional side view of a processing chamber in accordance with at least some embodiments of the present disclosure.

FIG. 2A is a side-view of a non-dispersive infrared sensor in accordance with at least some embodiments of the present disclosure.

FIG. 2B is diagram of an intensity of transmitted light and an intensity of received light in accordance with at least some embodiments of the present disclosure.

FIG. 3 is a flowchart of a method for processing a substrate in accordance with at least some embodiments of the present disclosure.

FIG. 4 is a diagram of a processing chamber in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods, apparatus, and systems that use a non-dispersive infrared (NDIR) sensor assembly for processing a substrate are provided herein. The inventors have found that a processing chamber comprising the NDIR sensor assembly described herein can provide advantages over other conventional chamber diagnostic systems. For example, the NDIR sensor assembly can directly measure chemicals present in the processing chamber. In addition, the NDIR sensor assembly can be coated with one or more materials to prevent corrosion of the NDIR sensor assembly in the highly caustic environments within the processing chamber. Moreover, chemical byproduct deposited on the NDIR sensor assembly can be removed using a heater that can be provided as a component of the NDIR sensor assembly or in a vicinity of the NDIR sensor assembly.

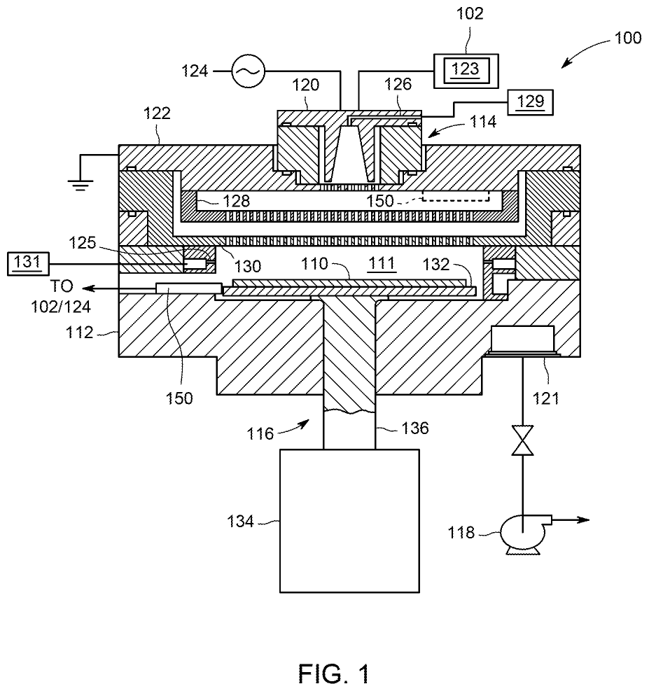

FIG. 1 is a cross sectional side view of a processing chamber 100 in accordance with at least some embodiments of the present disclosure. The processing chamber 100 is configured to perform one or more processes on a substrate 110. For example, in some embodiments, the processing chamber 100 can be a chemical vapor deposition chamber (CVD) configured to perform a CVD process, a physical vapor deposition (PVD) chamber configured to perform a PVD process, clean or preclean chamber configured to perform a cleaning or preclean process, and/or an etch chamber configured to perform an etching process on a substrate. For example, the processing chamber 100 can be configured for performing a thermal or plasma-based cleaning process and/or a plasma assisted dry etch process when processing the substrate 110. Apparatus that can be configured for performing a cleaning or an etch process with the NDIR sensor assembly described herein can be the SELECTRA® line of apparatus available from Applied Materials, Inc. located in Santa Clara, Calif. Apparatus that can be configured for performing a pre-cleaning process and/or a PVD with the NDIR sensor assembly described herein can be any of the ENDURA line of apparatus available from Applied Materials, Inc. located in Santa Clara, Calif. Apparatus that can be configured for performing a CVD with the NDIR sensor assembly described herein can be any of the PRODUCER® line of apparatus available from Applied Materials, Inc. located in Santa Clara Calif. Other apparatus available from Applied Materials, Inc., as well as those available from other manufacturers, may also be modified in accordance with the teachings disclosed herein. Such apparatus can be stand-alone apparatus, or one or more of the apparatus can be combined in a cluster tool.

Although the process chamber 100 may be configured for processing a substrate using other technique as disclosed herein, for illustrative purposes, the processing chamber 100 is assumed to be configured to perform a cleaning process and/or a plasma assisted dry etch process on the substrate 110. Accordingly, in some embodiments, the processing chamber 100 includes a chamber body 112, a lid assembly 114, and a support assembly 116. The lid assembly 114 is disposed at an upper end of the chamber body 112, and the support assembly 116 is at least partially disposed within an inner volume 111 defined within the chamber body 112. A vacuum system can be used to evacuate/remove process gases (and/or chemical byproduct removed from an IR sensor assembly and/or components associated therewith) from processing chamber 100, and can includes a vacuum pump 118 coupled to a vacuum port 121 disposed in the chamber body 112.

The processing chamber 100 also includes or is in communication with a controller 102 (or processor) for controlling processes within the processing chamber 100. The controller 102 includes a memory 123 (a non-transitory computer readable storage medium) having stored thereon instructions that when executed cause the controller 102 to perform a method for processing the substrate 110, including any of the methods disclosed herein. For example, in some embodiments, the controller 102 can be configured or programmed to tune an IR light source to one or more frequencies corresponding to various chemicals present in the processing chamber 100, as will be described in greater detail below.

The lid assembly 114 includes at least two stacked components configured to form a plasma volume or cavity. A first electrode 120 is disposed vertically above a second electrode 122 to define a plasma volume. The first electrode 120 is connected to a power source 124 (e.g., a radio frequency (RF) power supply and/or a DC power supply), and the second electrode 122 is connected to ground or a reference potential, forming a capacitance between the first electrode 120 and the second electrode 122.

The lid assembly 114 also includes one or more gas inlets 126 to which a gas supply 129 can be coupled for providing the process gas (e.g., a cleaning gas or etchant gas) to a surface of the substrate 110 through a blocker plate 128 and a gas distribution plate 130, such as a showerhead. The process gas may use radicals of a plasma formed from one or more suitable process gases. For example, in some embodiments the process gas can include, but is not limited to, hydrogen (H₂), helium (He), argon (Ar), ammonia (NH₃), water (H₂O), a fluorine containing gas such as nitrogen trifluoride (NF₃), hydrogen fluoride (HF), silicon tetrafluoride (SiF₄), or any combination of these gases.

Alternatively or additionally, a remote plasma source 131 containing the process gases can be configured to introduce the process gases (e.g., activated process gas in plasma form including ions and radicals) into the processing chamber 100. For example, the remote plasma source can be coupled to a separate gas inlet 125 disposed at a side of the chamber body 112 for introducing the process gases directly into the inner volume 111. In some embodiments, the remote plasma source 131 can advantageously provide the cleaning gas (e.g., plasma) through the gas inlet 125 and the gas supply 129 to provide the etchant gas through the gas distribution plate 130, or vice versa.

The support assembly 116 includes a substrate support 132 that has a flat, or a substantially flat, substrate supporting surface for supporting the substrate 110 during processing. The substrate support 132 may be coupled to an actuator 134 by a shaft 136 which extends through a centrally-located opening formed in a bottom of the chamber body 112. The actuator 134 may be flexibly sealed to the chamber body 112 by bellows (not shown) that prevent vacuum leakage around the shaft 136. The actuator 134 allows the substrate support 132 to be moved vertically within the chamber body 112 between one or more processing positions and a loading position. The loading position is slightly below an opening of a slit valve formed in a sidewall of the chamber body 112 for loading the substrate 110 onto the substrate support 132. The processing positions can be changed as the substrate 110 is being processed. For example, the substrate support 132 can be elevated from a first processing position where the substrate 110 is in close proximity to an infrared (IR) sensor assembly 150 to a second processing position where the substrate 110 is in close proximity to the lid assembly 114 to control a temperature of the substrate 110, e.g., so that the substrate 110 may be heated via radiation emitted or convection from the gas distribution plate 130.

Disposed within the inner volume 111 of the processing chamber 100 is the IR sensor assembly 150. The IR sensor assembly 150 can generally be disposed anywhere within the inner volume 111 of the processing chamber 100. For example, IR sensor assembly 150 can be disposed on or adjacent to the lid assembly 114, the blocker plate 128, the gas distribution plate 130, a floor of the inner volume adjacent the substrate support 132, or on the surface of the substrate support 132 adjacent the substrate 110. For example, in FIG. 1, the IR sensor assembly 150 is shown disposed on a floor within the inner volume 111 adjacent the substrate support 132.

In some embodiments, a plurality of IR sensors 150 can be provided in the inner volume 111 of the processing chamber 100. For example, two or more IR sensors 150 can be disposed in different locations of the inner volume 111 to collect a larger sample size. In some embodiments, for example, as shown in FIG. 1, a second IR sensor assembly 150 (shown in phantom) can be disposed on a ceiling within the inner volume 111 adjacent the lid assembly 114.

The IR sensor assembly 150 can be any suitable IR sensor assembly. For example, the IR sensor assembly 150 can be a Fourier Transformed IR (FTIR) sensor assembly, an NDIR sensor assembly, etc. The inventors have found that the FTIR sensor assembly can be expensive, and can have a complexity which can make the FTIR sensor assembly difficult to configure for use within the inner volume 111 of the processing chamber 100. Conversely, the inventors have found that the NDIR sensor assembly is relatively inexpensive and includes simple hardware that makes NDIR sensor assembly easy to configure for use within the inner volume of the processing chamber 100. Additionally, the inventors have found that the NDIR sensor assembly is more effective for measuring chemicals present within the, typically, highly caustic environment found within the inner volume 111 of the processing chamber 100 (e.g., when performing a cleaning and/or an etching process).

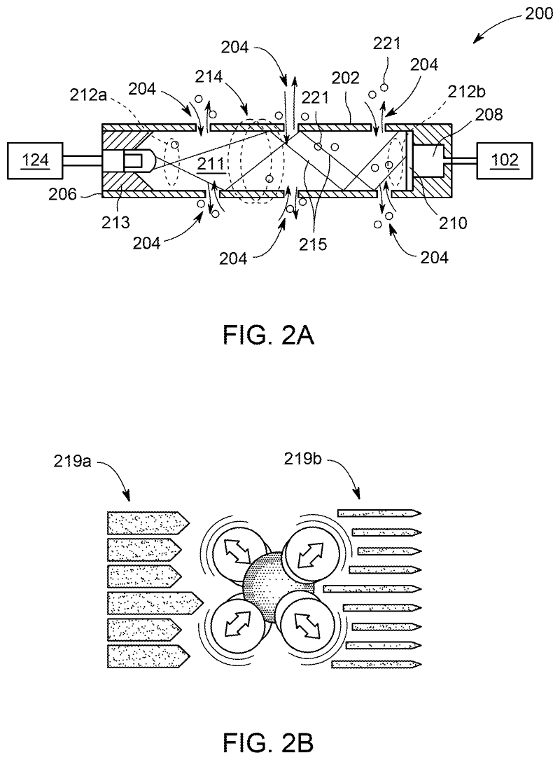

FIG. 2A is a side-view of an NDIR sensor assembly 200 (NDIR 200) in accordance with at least some embodiments of the present disclosure. The NDIR 200 includes a sample chamber 202 (e.g., optical waveguide) configured to collect chemicals which are present while processing the substrate 110 in the inner volume 111 of processing chamber 100, e.g., during a cleaning and/or an etching process More particularly, the sample chamber 202 can include one or more apertures 204 (six apertures 204 are shown) that are disposed along and defined through an outer surface of the sample chamber 202. More or fewer apertures 204 can be used to collect chemicals. The apertures 204 are configured to allow chemicals to pass therethrough and into an inner volume 211 of the sample chamber 202 while the substrate 110 is being processed. For example, depending on the process gas that is used to process the substrate 110 and the material that is being etched off the substrate 110, some of the chemicals that can pass through the apertures 204 and into inner volume 211 of the sample chamber 202 can include, but are not limited to, hydrogen (H₂), helium (He), carbon (C), oxygen (O₂), nitrogen (N₂), silicon (Si), argon (Ar), water (H₂O), hydrogen fluoride (HF), hydrogen chloride (HCl), carbon dioxide (CO₂), ammonia (NH₃), a fluorine containing gas such as silicon tetrafluoride (SiF₄) or nitrogen trifluoride (NF₃).

The apertures 204 can have the same size or different size. Moreover, the apertures 204 can have any suitable geometric configuration including, but not limited to, rectangular, circular, oval, triangular, elliptical, irregular, and/or other suitable configuration. In some embodiments, the apertures 204 can be similarly or differently configured, e.g., some can be rectangular and some can be circular.

An IR light source 206 is disposed at one end of the sample chamber 202 and an IR detector 208 is disposed at an opposite end of the sample chamber 202. The IR light source 206 can be any device suitable for creating light including, but not limited to, a lamp, one or more light emitting diodes (LEDs), single mode laser diode, etc. The IR detector 208 can be any device suitable for measuring infrared radiation including, but not limited to, Indium gallium arsenide (InGaAs) detector, polycrystalline lead (PbS) detector, pyroelectric sensor, etc.

The IR light source 206 is connected to one or more power sources. For example, in some embodiments, the IR light source 206 can be connected to the power source 124 for receiving power to generate light at one or more frequencies (e.g., IR light). Alternatively or additionally, one or more other power sources (e.g., a dedicated DC power source) can be provided on or coupled to the processing chamber 100 and configured to supply power to the IR light source 206. The IR detector is operably connected (e.g., via a wired or wireless interface) to the controller 102 for providing a signal (e.g., including data, information, etc.) to the controller 102 for determining a concentration of chemicals present in the processing chamber 100 while processing the substrate 110, as will be described in greater detail below.

Disposed adjacent the IR detector 208 and interposed between the IR detector 208 and the IR light source 206 can be one or more suitable filters 210 (e.g., bandpass filter) that can be used to filter infrared light transmitted from the IR light source 206. The filter 210 is configured to remove noise caused by one or more chemicals (e.g., process gases, chemical byproduct, etc.) inadvertently collected in the sample chamber 202 during processing of the substrate 110. The filter 210 is configured so that the IR detector 208 primarily receives radiation of a wavelength that is strongly absorbed by a chemical whose concentration is to be determined, as will be described in greater detail below. Similarly, disposed adjacent the IR light source can be one or more reflectors (or beam concentrators) 213 that can be configured to reflect the IR light generated by the IR light source 206 along an optical path 215 and toward the IR detector 208 (see FIG. 2B, for example).

A pair of windows 212a, 212b adjacent each of the IR light source 206 and the IR detector 208, respectively, are positioned in the optical path 215 between the IR light source 206 and the IR detector 208. The pair of windows 212a, 212b isolate the IR light source 206 and IR detector 208 from the process gas that passes through the apertures 204 and into the inner volume 111 of the process chamber 100, to protecting the IR light source 206 and IR detector 208 from the highly corrosive process gas used for processing (e.g., cleaning and/or etching) the substrate 110.

The pair of windows 212a, 212b can be made from any suitable material (e.g., a material that will not readily react with the process gas) including, but not limited to, calcium fluoride (CaF₂), barium fluoride (BaF₂), potassium bromide (KBr), magnesium fluoride (MgF₂), silicon, fused silica, germanium, and/or zinc. For example, the inventors have found, through empirical data, that when the NDIR 200 is used in a processing chamber 100 that is configured for performing a cleaning or etching process on the substrate 110 (e.g., in a caustic environment, such as when the process gas is HF), the pair of windows 212a, 212b perform particularly well when made from silicon, which does not readily react with the HF and provides good transmission of the IR light transmitted from the IR light source 206 to the IR detector.

Likewise, the sample chamber 202 can be made from and/or coated with one or more suitable materials (e.g., a material that will not readily react with the process gas), including, but not limited to, nickel (Ni), low carbon Ni, or Ni alloy that comprises Ni and copper (Cu), chromium (Cr), molybdenum (Mo), and/or iron (Fe). For example, the inventors have found, through empirical data, that when the NDIR 200 is used in a processing chamber 100 that is configured for performing a cleaning or etching process on the substrate 110 (e.g., in a caustic environment), coating the sample chamber 202 with nickel or low carbon Ni provides superior corrosion resistance with respect to, for example, HF.

A heating assembly 214 includes one or more heating elements that are configured to heat the NDIR 200 for removing chemical byproduct, which can be in a liquid or solid state, accumulated on the NDIR 200 and components thereof, e.g., the sample chamber 202. Such a process can be performed as part of routine maintenance of the processing chamber 100 and/or the NDIR 200.

The heating elements can be any suitable type of heating element including, but not limited to, lamps, coils, etc. In some embodiments, the heating assembly 214 includes one or more heating coils 216 (two heating coils are shown in FIG. 2A). The one or more heating coils 216 can be coupled to the power source 124 (or other power source, such as the same dedicated power source configured to power the IR light source 206) for heating thereof. The one or more heating coils are used to heat the sample chamber 202 to a temperature suitable to vaporize or sublimate chemical byproduct accumulated on the NDIR 200 and components thereof, e.g., the sample chamber 202. For example, in some embodiments, the one or more heating coils 216 are configured to heat the sample chamber 202 to a temperature of about 80° C. to about 150° C.), or in some embodiments, about 100° C., or greater than 150° C.

Alternatively or additionally, the heating assembly 214 can be positioned anywhere within the inner volume 111, as long as the heating assembly 214 is close enough to the NDIR 200 so that the sample chamber 202 can be heated to temperatures equal to about 80° C. to about 150° C.

In some embodiments, the heating assembly 214 can be omitted, and the sample chamber 202 can be heated to the above referenced temperatures using, for example, the radiation emitted or convection from the gas distribution plate 130 (e.g., when the NDIR 200 is coupled to the substrate support 132).

As noted above, the vacuum pump 118 coupled the vacuum system can be used to evacuate/remove, via the vacuum port 121, gas (e.g., the sublimated chemical byproduct that was accumulated on the sample chamber 202).

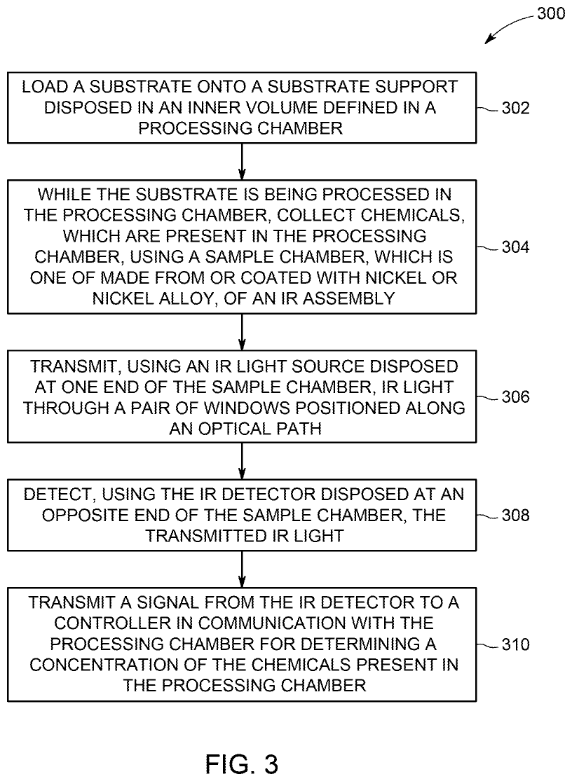

FIG. 3 is a flowchart of a method 300 for processing a substrate using, for example, the processing chamber 100. For example, as noted above, the processing chamber 100 can be configured to perform CVD, PVD, a cleaning or preclean process, and/or an etching process on a substrate, using one or more of the above described process gases. For illustrative purposes, it is assumed that the processing chamber 100 is configured to perform an etching process on the substrate 110 to remove some of a top layer of material, e.g., SiO, from the substrate 110, using for example, HF, and that the NDIR 200 is configured to collect chemicals, present while processing the substrate 110 during the etching process.

At 302, the substrate 110 can be loaded onto the substrate support 132 disposed in the inner volume 111 defined in a processing chamber 100. As noted above, the substrate support 132 can be moved to the second position so that the substrate 110 can be loaded on the substrate support 132. Next, the substrate support 132 can be moved to a processing position, e.g., adjacent the NDIR 200, which is disposed on the floor within the inner volume 111 of the processing chamber 100.

The controller 102 can control the components of the processing chamber 100 to carry out instructions based on information included in a recipe that was previously input to, for example, the memory 123. The information included in the recipe can include, for example, a substrate support 132 processing position (e.g., adjacent the NDIR 200 or one or more processing positions), a temperature and pressure which the substrate 110 is to be processed at, temperature and pressure up/down step times, etch start and end times, such as etch time end points, a material that the substrate 110 is formed from, a material of the layer that is to be etched, type of process gas, etc.

Next, at 304 while the substrate 110 is being processed in the processing chamber 100, the sample chamber 202 of the NDIR 200 can collect chemicals, present while processing the substrate 110 in the processing chamber 100. More particularly, as the SiO is being etched off the substrate 110, for example, using HF, chemical byproduct 221, which can include the etched SiO, passes through the apertures 204 defined through the sample chamber 202 and is collected within the inner volume 211 of the sample chamber 202.

The controller 102 can detect an amount of the SiO in the chemical byproduct 221 while the substrate 110 is being etched. More particularly, at 306 the controller 102 can send a control signal to the IR light source 206 to transmit light at one or more frequencies, e.g., IR light tuned to a specific frequency for detecting SiO, through the pair of windows 212a, 212b, which are positioned along the optical path 215. The transmitted IR light will be directed toward the IR detector 208, and can be reflected multiple times as the IR light progresses along the length of the sample chamber 202. As the transmitted IR light progresses along the length of the sample chamber 202, the light intensity of the transmitted IR light, due to absorption of the SiO present in the collected chemical byproduct 221, will weaken or decrease. For example, an intensity of the IR light transmitted from IR light source 206 prior to being transmitted through the window 212a will have a maximum intensity (as depicted by arrows 219a of FIG. 2B), and an intensity of the IR light detected at the IR detector 208 after to being received through the window 212b will have a minimum intensity (as depicted by arrows 219b of FIG. 2B). The controller 102 can tune the IR light source 206 to transmit the IR light at a frequency that will detect only the SiO in the chemical byproduct 221, thus reducing and/or removing noise that can be created by other chemicals in the chemical byproduct. For example, some of the chemical byproduct 221 collected within the sample chamber 202 can include HF and/or Si, but since the IR light source 206 transmits IR light at a frequency tuned to only detect SiO, the other chemicals in the chemical byproduct will not be detected.

Next, at 308, the IR detector 208 can detect the transmitted IR light and at 310 can transmit a signal, based on the detected IR light, to the controller 102 for determining a concentration of chemicals (e.g., SiO) present in the processing chamber, e.g., based on the collected chemical byproduct 221.

In some embodiments, as noted above, multiple NDIRs can be disposed at different locations within an inner volume of a processing chamber. For example, if a recipe for processing a substrate requires moving a substrate support to multiple processing positions, two or more NDIRs 200 can be used.

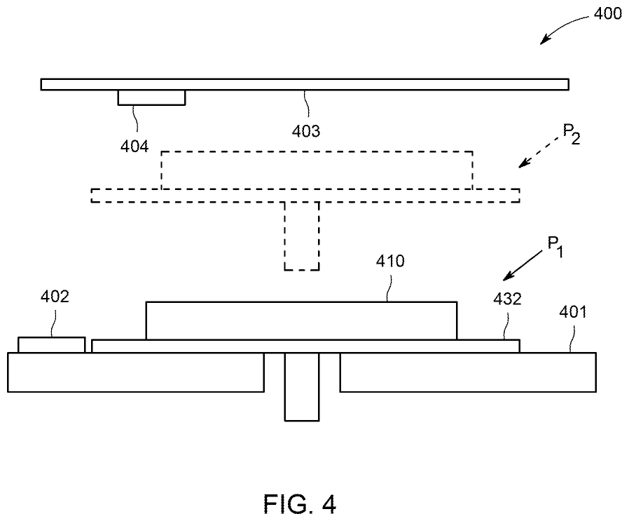

More particularly, FIG. 4 illustrates a processing chamber 400, which can be configured similarly to the processing chamber 100, including two NDIRs 402, 404, which can be identical to the NDIR 200. For illustrative purposes, a blocker plate and a gas distribution plate of the processing chamber 400 are not shown. As described above, the NDIR 402 can be positioned on a floor 401 of the processing chamber 400 adjacent a substrate support 432 that supports a substrate 410, and the NDIR 404 can be positioned on a ceiling 403 of the processing chamber 400. In some embodiments, the NDIR 402 can advantageously be disposed directly on the substrate support 432 adjacent the substrate 410.

Accordingly, if a recipe includes a first processing position P1 and a second processing position P2 for processing the substrate 410, at the first processing position P1, a controller, e.g., the controller 102, can perform 302-310 using, for example, information provided by the NDIR 402 and components associated therewith. At the etch end point of the first processing position P1 (not shown to scale), the controller can move the substrate support 432 to the second processing position P2 (shown in phantom and not shown to scale) and can again perform 302-310 using, for example, information provided by the NDIR 404 and components associated therewith. At the etch end point of the second processing position P2, the controller can move the substrate support 432 back to the first processing position P1 and/or an unloading position for unloading the substrate 410 from the processing chamber 400.

Prior to performing 302-310 at the second processing position, the controller can use a vacuum pump, e.g., the vacuum pump 118, to remove/evacuate, for example, process gas (and/or chemical byproduct) that may be present in the inner volume of the processing chamber 400 and/or the inner volume of the respective NDIR 402 and NDIR 404. Alternatively or additionally, the controller can heat the NDIR 402 and NDIR 404 using, for example, respective heating assemblies of the respective NDIR 402 and NDIR 404.

While the foregoing is directed to embodiments of the present disclosure, other and further embodiments of the disclosure may be devised without departing from the basic scope thereof.

1. A system for processing a substrate, comprising:
a controller;
a processing chamber defining an inner volume;
a substrate support disposed in the processing chamber to support a substrate; and
an infrared (IR) sensor assembly disposed in the inner volume of the processing chamber adjacent the substrate support and comprising:
a sample chamber one of made from or coated with nickel or nickel alloy and configured to collect chemicals which are present while the substrate is being processed in the processing chamber;
an IR light source disposed at one end of the sample chamber and an IR detector disposed at an opposite end of the sample chamber; and
a pair of windows positioned in an optical path between the IR light source and the IR detector,
wherein the IR light source transmits IR light along the optical path and the IR detector detects the transmitted IR light and transmits a signal to the controller for determining a concentration of the chemicals present in the processing chamber.

2. The system according to claim 1, wherein the pair of windows are made from one of silicon, germanium, or fused silica.

3. The system according to claim 1, further comprising two IR sensor assemblies disposed at different locations within the inner volume of the processing chamber.

4. The system according to claim 1, wherein the processing chamber is one of a physical vapor deposition chamber, a chemical vapor deposition chamber, a preclean chamber, or an etch chamber.

5. The system according to claim 1, wherein the chemicals that the sample chamber collects includes at least one of hydrogen (H₂), helium (He), carbon (C), oxygen (O₂), nitrogen (N₂), silicon (Si), argon (Ar), water (H₂O), hydrogen fluoride (HF), hydrogen chloride (HCl), carbon dioxide (CO₂), ammonia (NH₃), silicon tetrafluoride (SiF₄) or nitrogen trifluoride (NF₃).

6. The system according to claim 1, further comprising a heating assembly configured to heat the IR sensor assembly for removing chemical byproduct accumulated on the IR sensor assembly.

7. The system according to claim 6, further comprising a vacuum pump configured to evacuate from the processing chamber chemical byproduct removed from the IR sensor assembly.

8. The system according to claim 1, wherein the controller is configured to tune the IR light source to at least one frequency corresponding to the chemicals present in the processing chamber.

9. The system according to claim 1, wherein the sample chamber is further configured to collect the chemicals through an aperture defined through the sample chamber.

10. A method for processing a substrate, comprising:
loading a substrate onto a substrate support disposed in an inner volume defined in a processing chamber;
while the substrate is being processed in the processing chamber, collecting chemicals present in the processing chamber, using a sample chamber made from or coated with nickel or a nickel alloy, wherein the sample chamber is part of an IR sensor assembly;
transmitting, using an IR light source disposed at one end of the sample chamber, IR light through a pair of windows positioned along an optical path;
detecting, using an IR detector disposed at an opposite end of the sample chamber, the transmitted IR light; and
transmitting a signal from the IR detector to a controller in communication with the processing chamber for determining a concentration of the chemicals present in the processing chamber.

11. The method according to claim 10, wherein the pair of windows are made from one of silicon, germanium, or fused silica.

12. The method according to claim 10, wherein collecting chemicals comprises using two sample chambers of two IR sensor assemblies.

13. The method according to claim 10, wherein the substrate is processed using one of a physical vapor deposition chamber, a chemical vapor deposition chamber, a preclean chamber, or an etch chamber.

14. The method according to claim 10, wherein collecting the chemicals comprises collecting at least one of hydrogen (H₂), helium (He), carbon (C), oxygen (O₂), nitrogen (N₂), silicon (Si), argon (Ar), water (H₂O), hydrogen fluoride (HF), hydrogen chloride (HCl), carbon dioxide (CO₂), ammonia (NH₃), silicon tetrafluoride (SiF₄) or nitrogen trifluoride (NF₃).

15. The method according to claim 10, further comprising heating the IR sensor assembly to a temperature sufficient to remove chemical byproduct accumulated on the IR sensor assembly.

16. The method according to claim 15, further comprising evacuating, using a vacuum pump, from the processing chamber chemical byproduct removed from the IR sensor assembly.

17. The method according to claim 10, further comprising tuning, using the controller, the IR light source to at least one frequency corresponding to the chemicals present in the processing chamber.

18. A non-transitory computer readable storage medium having stored thereon a plurality of instructions that when executed cause a controller in communication with a processing chamber to perform a method for processing a substrate, comprising:
loading a substrate onto a substrate support disposed in an inner volume defined in the processing chamber;
while the substrate is being processed in the processing chamber, collecting chemicals, which are present in the processing chamber, using a sample chamber, which is one of made from or coated with nickel or nickel alloy, of an IR sensor assembly;
transmitting, using an IR light source disposed at one end of the sample chamber, IR light through a pair of windows positioned along an optical path;
detecting, using an IR detector disposed at an opposite end of the sample chamber, the transmitted IR light; and
transmitting a signal from the IR detector to the controller in communication with the processing chamber for determining a concentration of the chemicals present in the processing chamber.

19. The non-transitory computer readable storage medium according to claim 18, wherein the method for processing the substrate further comprises heating the IR sensor assembly to a temperature sufficient to remove chemical byproduct accumulated on the IR sensor assembly.

20. The non-transitory computer readable storage medium according to claim 18, wherein the method for processing the substrate further comprises evacuating, using a vacuum pump, from the processing chamber chemical byproduct removed the IR sensor assembly.
